(19) United States
(12) Patent Application Publication
(10) Pub. No.: US 2017/0205041 A1
(43) Pub. Date: Jul. 20, 2017

(54) LED AUTOMOBILE BULB

(71) Applicant: Heshan Jianhao Lighting Industrial Co., Ltd., Heshan City (CN)

(72) Inventor: KUO-HAO HUANG, Taibei City (CN)

(21) Appl. No.: 15/402,373

(22) Filed: Jan. 10, 2017

(30) Foreign Application Priority Data
Jan. 19, 2016 (CN) 2016200538150

(51) Int. Cl. F21S 8/10; H01L 33/62

(52) U.S. Cl. CPC F21S 48/212; F21S 48/115; F21S 48/215; F21S 48/33; F21S 48/1109; F21S 48/1233; H01L 33/62; H01L 33/34

(57) ABSTRACT

An LED automobile bulb includes a housing, a holder fixedly connected with the housing and an LED luminous assembly which includes a driver board, wherein: the LED luminous assembly further includes an LED light source arranged above the driver board, and bracket guide wires. One of the wires is electrically connected with the LED light source and used for supporting and positioning the LED light source, at one end; the other end of the bracket guide wire is electrically connected with the driver board. The LED light source includes one or more LED luminous strip packaged by means of COB.

### CROSS-REFERENCE TO RELATED APPLICATION

The present application claims priority from Chinese Patent Application No. 2016200538150 filed on Jan. 19, 2016, the content of which is hereby incorporated by reference into this application.

### FIELD OF THE INVENTION

The invention relates to an LED (Light-Emitting Diode) automobile bulb.

### BACKGROUND OF THE INVENTION

With the development of economy, LEDs are applied more and more widely. An automobile bulb is also developed from a conventional halogen bulb to an LED bulb which is applied in vehicle in interior lamps or external warning lamps, such as a brake lamp, a turn signal light and the like, in which the LEDs, as a point light source, have the characteristics of small light emitting surface area and large luminous flux. With the gradual maturity of LED technology and reduction of manufacturing cost, it has become an irresistible trend that the LEDs are used in automobile lamps. Currently, an LED automobile bulb is formed by arranging a plurality of low-power LED lamp beads on a PCB (Printed Circuit Board) and combining a plurality of luminous panels, thus it is difficult to produce the LED bulb in complex assembling process due to numerous welding spots. Additionally, such LED automobile bulb needs to collocate with a lens and a heat dissipation member, resulting in large volume, high cost, and even the quality problem influenced by heat dissipation and luminous decay in the bulb.

### SUMMARY OF THE INVENTION

In order to overcome the defects in the prior art, the invention provides an LED automobile bulb using an LED luminous strip as a light source, which has few welding spots, is simple in assembling process, is convenient to produce and does not need to collocate with a lens and a heat dissipation member.

In order to solve the technical problems, the invention adopts the following technical solution.

An LED automobile bulb includes a housing, a holder fixedly connected with the housing and an LED luminous assembly comprising a driver board. The LED luminous assembly further includes an LED light source arranged above the driver board, and bracket guide wires, each of the bracket guide wires is electrically connected with the LED light source and used for supporting and positioning the LED light source, at one end; the other end of the bracket guide wire is electrically connected with the driver board; and the LED light source is an LED luminous strip packaged by means of COB.

Further, one LED luminous strip is provided.

Still further, more than one LED luminous strips are provided.

Still further, the LED luminous strip includes a substrate and an LED chip COB packaged on the substrate.

Still further, the substrate is made of a heat conduction material.

Still further, the housing is filled with nitrogen.

Still further, the LED luminous assembly is fixed in the holder.

Still further, the housing is made of glass or transparent plastic.

Still further, the housing and the holder are sealed and combined by an adhesive.

The invention has the beneficial effects that, instead of using a plurality of luminous panels which are combined to form the LED automobile lamp, the COB packaged LED luminous strip is used as the LED light source which is electrically connected with the bracket guide wires which play a role of supporting and positioning the LED light source and are electrically connected with the driver board at the other ends, so that the LED automobile bulb has few welding spots, and is simple in assembling process and convenient to produce. The LED light source is suspended to facilitate heat dissipation. The LED automobile bulb does not need to be used in conjunction with the lens and the heat dissipation member, so that the bulb is small in size and low in cost, and the quality of the bulb cannot be influenced by the problems of heat dissipation and luminous decay.

### BRIEF DESCRIPTION OF THE DRAWINGS

The invention will be further illustrated below by reference to the embodiments in conjunction with the accompanying drawings, wherein:

FIG. 1 depicts an exemplary structural of an LED automobile bulb according to embodiment 1 of the invention;

FIG. 2 depicts another exemplary structural of the LED automobile bulb according to embodiment 1 of the invention; and

FIG. 3 depicts an exemplary structural of the LED automobile bulb according to embodiment 2 of the invention.

### DETAILED DESCRIPTION OF THE EMBODIMENTS

Embodiment 1

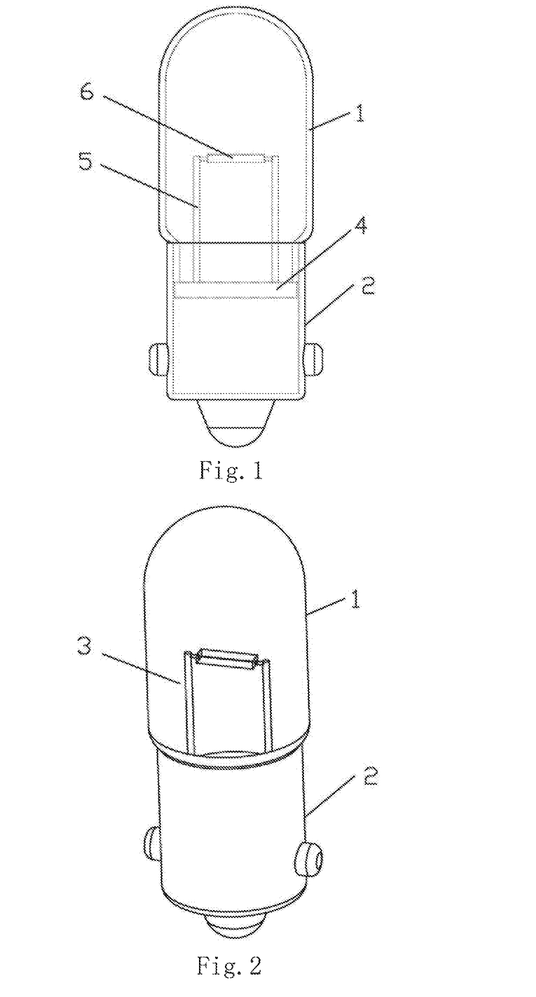

With reference to FIGS. 1 to 2, an LED automobile bulb includes a housing 1, a holder 2 fixedly connected with the housing 1 and an LED luminous assembly 3. The LED luminous assembly 3 includes a driver board 4, bracket guide wires 5 and an LED light source 6 arranged above the driver board 4, wherein each of the bracket guide wires at one end is electrically connected with the LED light source 6 and used for supporting and positioning the LED light source 6, at the other end is electrically connected with the driver board 4, and the LED light source 6 includes at least one LED luminous strips packaged by means of COB.

The COB packaged LED luminous strip is used as the LED light source 6 which is electrically connected with the bracket guide wires 5. Metal electrodes for electrical connection are arranged at both ends of the LED luminous strip and are electrically connected to the driver board 4 positioned inside the holder 2 by two rigid bracket guide wires 5. The LED luminous strip can be conveniently positioned by setting a distance from the bracket guide wires 5 to the driver board 4, so as to ensure the uniformity of a light center in batch production and quality stability of the product. Since the LED automobile bulb does not need to be manufactured by combining a plurality of luminous panels, it has few welding spots, and is simple in assembling process and convenient to produce. The LED light source is suspended to facilitate heat dissipation. The LED automobile bulb does not need to collocate with a lens and a heat dissipation member, so that the bulb is small in size and low in cost, and quality of the bulb cannot be influenced by the problems of heat dissipation and luminous decay.

In the embodiment, preferably, the amount of the LED luminous strip is one, so that the LED automobile bulb is simple in structure.

In the embodiment, preferably, the LED luminous strip includes a substrate and LED chips packaged by means of COB on the substrate. The COB packaged LED luminous strip has a wide light emitting angle, such as 360 degrees; meanwhile, the LED automobile bulb has an appearance similar to a conventional tungsten lamp and more excellent luminous efficiency. COB (chip-on-board) refers to a process that: firstly, a silicon wafer placement point is covered with heat conducting epoxy resin (generally, epoxy resin doped with silver particles) on the surface of the substrate; then a silicon wafer is directly placed on the surface of the substrate and subjected to thermal treatment until the silicon wafer is firmly fixed on the substrate; and an electrical connection is directly established between the silicon wafer and the substrate by a wire welding method.

In the embodiment, preferably, the substrate is made of a heat conduction material, which is beneficial to heat dissipation.

In the embodiment, preferably, the housing 1 is filled with nitrogen, so that the performance of the bulb can be more stable by vacuuming and filling nitrogen, and moreover, the heat from the bulb can be dissipated better.

In the embodiment, preferably, the LED luminous assembly 3 is fixed in the holder 2, so that the LED automobile bulb is simple and practical.

In the embodiment, preferably, the housing 1 is made of glass or transparent plastic, so that the LED automobile bulb is simple in structure and low in cost.

In the embodiment, preferably, the housing 1 and the holder 2 are sealed and combined by an adhesive, enabling good protective performance of the product, thus internal components of the product may not be influenced by dust and moisture in environment.

### Embodiment 2

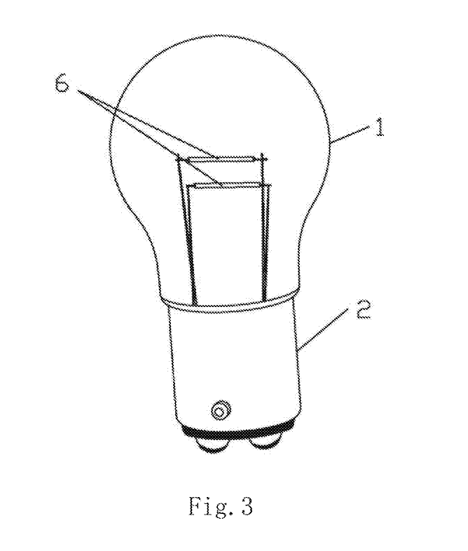

With reference to FIG. 3, the embodiment is difference from the embodiment 1 in that two LED luminous strip are provided to achieve a double-core filament structure, enabling a switching between high beam or low beam of a conventional automobile bulb.

The above are merely preferred embodiments of the invention, but the invention is not limited thereto. All embodiments should fall within the scope of protection of the invention as long as they achieve the technical effects of the invention using the same or similar means.

What is claimed is:

1. An LED automobile bulb, comprising
a housing,
a holder fixedly connected with the housing and
an LED luminous assembly including a driver board,
wherein the LED luminous assembly further includes an LED light source arranged above the driver board, and bracket guide wires, each of the bracket guide wires is electrically connected with the LED light source and used for supporting and positioning the LED light source at one end;
the other end of each of the bracket guide wires is electrically connected with the driver board; and
the LED light source includes at least one LED luminous strips packaged by means of COB.

2. The LED automobile bulb according to claim 1, wherein the amount of the LED luminous strip is one.

3. The LED automobile bulb according to claim 1, wherein the amount of the LED luminous strip is more than one.

4. The LED automobile bulb according to claim 1, wherein the LED luminous strip includes a substrate and an LED chip packaged on the substrate by means of COB.

5. The LED automobile bulb according to claim 4, wherein the substrate is made of a heat conduction material.

6. The LED automobile bulb according to claim 1, wherein the housing is filled with nitrogen.

7. The LED automobile bulb according to claim 1, wherein the LED luminous assembly is fixed in the holder.

8. The LED automobile bulb according to claim 1, wherein the housing is made of glass or transparent plastic.

9. The LED automobile bulb according to claim 1, wherein the housing and the holder are sealed and combined by an adhesive.
